(19) United States
(12) Patent Application Publication
(10) Pub. No.: US 2026/0214839 A1
(43) Pub. Date: Jul. 23, 2026

(54) COOLING PLATE

(71) Applicant: LG ELECTRONICS INC., Seoul (KR)

(72) Inventors: Taekyung OH, Seoul (KR); Hyeuk CHANG, Seoul (KR); Hoon CHO, Seoul (KR); Minjoong KIM, Seoul (KR)

(73) Assignee: LG ELECTRONICS INC., Seoul (KR)

(21) Appl. No.: 19/455,558

(22) Filed: Jan. 21, 2026

(30) Foreign Application Priority Data
Jan. 22, 2025 (KR) 10-2025-0009799
Dec. 31, 2025 (WO) PCT/KR2025/023341

(51) Int. Cl. H05K 7/20

(52) U.S. Cl. CPC H05K 7/20254; H05K 7/20263; H05K 7/20409; H05K 7/20772

(57) ABSTRACT

Provided is a cooling plate. The cooling plate has a sealing structure that suppresses leakage. The cooling plate is a cooling plate that removes heat from a circuit component, and includes an upper plate and a lower plate. The upper plate includes an inlet through which coolant flows in and an outlet through which the coolant flows out. The lower plate is coupled to the upper plate, and includes a plurality of cooling fins arranged thereon. The upper plate further includes an O-ring groove in which an O-ring member is arranged. When the upper plate and the lower plate are coupled, the O-ring member is compressed.

### CROSS-REFERENCE TO RELATED APPLICATION

Pursuant to 35 U.S.C. § 119(a), this application claims the benefit of the earlier filing date and the right of priority to Korean Patent Application No. 10-2025-0009799, filed on January 22, 2025, and benefit of the earlier filing date and the right of priority to International Patent Application No. PCT/KR2025/023341, filed on December 31, 2025, the contents of which are incorporated by reference herein in their entirety.

### BACKGROUND

### 1. Field

The disclosure relates to a cooling plate that removes heat generated from circuit components.

### 2. Description of the Related Art

Many electric cell devices include circuit components, such as high-performance processors, various sensors, graphics processing unit (GPU), central processing unit (CPU), and the like, and these circuit components generate a lot of heat during operation.

Therefore, a cooling plate is required to be attached to one surface of a circuit component, which is a high heat source, so as to cool the circuit component, and it is also required to suppress coolant from leaking from inside of the cooling plate to outside.

### SUMMARY

An aspect of the disclosure is to provide a cooling plate having a sealing structure for minimizing power consumption of a cooling system by minimizing pressure applied to cooling fins by coolant and for suppressing leakage of the coolant.

The above-described aspect of the disclosure is achieved by the specific contents described below.

The cooling plate according to an embodiment of the disclosure is a cooling plate that removes heat from a circuit component, and includes an upper plate and a lower plate. The upper plate includes an inlet through which coolant flows in and an outlet through which the coolant flows out. The lower plate is coupled to the upper plate, and includes a plurality of cooling fins arranged thereon. The upper plate further includes an O-ring groove in which an O-ring member is arranged. When the upper plate and the lower plate are coupled, the O-ring member is compressed.

Specifically, the upper plate further includes an upper plate groove accommodating the plurality of cooling fins. The O-ring groove is formed in a band shape with a preset width and surrounds the upper plate groove.

Specifically, the upper plate further includes a first coupling groove. The first coupling groove is formed in a band shape with a preset width and surrounds the O-ring groove.

Specifically, a first adhesive groove is formed in the first coupling groove. The first adhesive groove communicates with the first coupling groove and accommodates an adhesive member. The first adhesive groove is formed on a bottom surface of the first coupling groove and is formed by being recessed from the bottom surface of the first coupling groove toward an upper surface of the upper plate by a preset depth.

Specifically, the lower plate further includes a first coupling protrusion inserted into the first coupling groove. The first coupling protrusion is formed in a band shape with a preset width and is formed by protruding from an upper surface of the lower plate toward the upper plate by a preset length.

The cooling plate according to an embodiment of the disclosure further includes an adhesive member. The adhesive member is applied to the first coupling groove of the upper plate, so as to be arranged between the first coupling groove and the first coupling protrusion of the lower plate.

Specifically, the upper plate further includes a second coupling groove. The second coupling groove is formed in a band shape with a preset width and surrounds the first coupling groove.

Specifically, a second adhesive groove is formed in the second coupling groove. The second adhesive groove communicates with the second coupling groove and accommodates an adhesive member. The second adhesive groove is formed on a bottom surface of the second coupling groove and is formed by being recessed from the bottom surface of the second coupling groove toward an upper surface of the upper plate by a preset depth.

Specifically, the lower plate further includes a second coupling protrusion inserted into the second coupling groove. The second coupling protrusion is formed in a band shape with a preset width and is formed by protruding from an upper surface of the lower plate toward the upper plate by a preset length.

Specifically, the adhesive member is applied to the second coupling groove of the upper plate, so as to be arranged between the second coupling groove and the second coupling protrusion of the lower plate.

Specifically, the upper plate further include an inlet passage communicating with the inlet, an outlet passage communicating with the outlet, and an upper plate groove accommodating the plurality of cooling fins. A height of the cooling fin is equal to a depth of the upper plate groove.

Specifically, the upper plate groove and the lower plate each include a fin area where the plurality of cooling fins are arranged, and an edge area surrounding the fin area. Coolant flowing into the upper plate groove passes between the cooling fins, reaches the edge area, and moves along the edge area.

Specifically, a pair of inner partition walls are formed in the upper plate groove. The pair of inner partition walls are formed between the fin area and the edge area corresponding to a horizontal direction of the upper plate groove, to partition the fin area and the edge area.

Specifically, a first group and a second group each consisting of the plurality of cooling fins are arranged between the pair of inner partition walls. A longitudinal direction of the cooling fins is arranged parallel to a longitudinal direction of the inner partition walls.

Specifically, the first group and the second group are arranged spaced apart from each other by a certain distance in the fin area of the lower plate. The inlet passage of the upper plate is located above a space where the first group and the second group are spaced apart from each other.

A cooling plate according to the disclosure has a sealing structure (performance) superior to that of the related art cooling plate. Accordingly, coolant inside the cooling plate does not leak out of the cooling plate.

The cooling plate according to the disclosure minimizes pressure applied by coolant to cooling fins, thereby minimizing overall power consumption of a cooling system.

The cooling plate according to the disclosure distributes a flow rate of coolant flowing between cooling fins, thereby reducing pressure loss and improving cooling efficiency.

More detailed effects of the cooling plate according to the disclosure are described in the specific contents for carrying out the invention below.

### BRIEF DESCRIPTION OF THE DRAWINGS

The above and other aspects, features and other advantages of the present disclosure will be more clearly understood from the following detailed description taken in conjunction with the accompanying drawings, in which:

FIG. 1 is a view of a cooling plate according to an embodiment of the disclosure;

FIG. 2 is an inner perspective view of the cooling plate shown in FIG. 1;

FIG. 3 is a cross-sectional view of one side of the cooling plate shown in FIG. 1;

FIG. 4 is a perspective view of an upper plate in a portion A of FIG. 3;

FIGS. 5 and 6 are views of the upper plate of FIG. 1 in a turn-over state;

FIG. 7 is a view of a lower plate and cooling fins of FIG. 1;

FIG. 8 is a view of the portion A of FIG. 3;

FIG. 9 is a view of a portion where an adhesive member is applied in FIG. 8; and

FIG. 10 is a brief view of a different cooling plate.

### DETAILED DESCRIPTION OF THE INVENTION

Hereinafter, embodiments of the disclosure will be described in detail with reference to the accompanying drawings. A detailed description of components of the disclosure that may be clearly understood and easily reproduced by a person skilled in the art using the related art will be omitted, not to obscure the gist of the disclosure.

It should be noted that the attached drawings are provided to facilitate understanding of the embodiments disclosed in this specification, and should not be construed as limiting the technical idea disclosed in this specification by the attached drawings.

A singular representation may include a plural representation unless it represents a definitely different meaning from the context.

It will be understood that although the terms first, second, etc. may be used herein to describe various elements, these elements should not be limited by these terms. These terms are generally only used to distinguish one element from another. For example, without departing from the scope of the disclosure, a first component may be referred to as a second component, and similarly, the second component may also be referred to as the first component.

Hereinafter, a cooling plate according to an embodiment of the disclosure is described.

A cooling plate according to the disclosure is a cooling device for removing (dissipating) heat generated from circuit components on a printed circuit board of an electrical and electronic device.

For example, the cooling plate according to the disclosure is a cooling device that is attached to an upper surface of a chip, such as a central processing unit (CPU) or graphic processing unit (GPU), which is a high heat source of a server installed in a data center, to cool the high heat source.

When coolant leaks outside the cooling plate, the coolant not only damages the circuit components but also makes it difficult to restore the electrical and electronic device to a normal state, resulting in significant damage.

The cooling plate according to the disclosure has an excellent sealing structure (performance) which suppresses leakage of coolant while effectively removing heat generated from the circuit components.

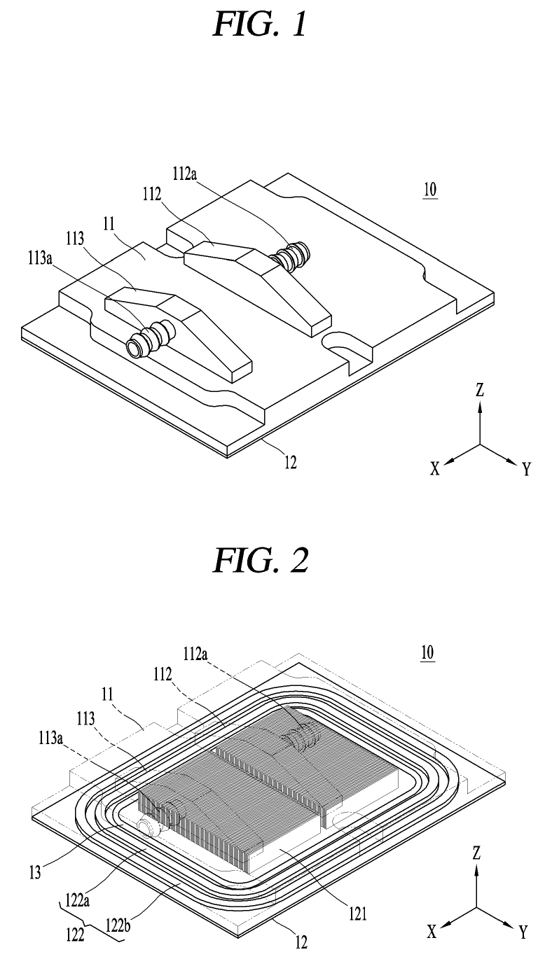

Referring to FIGS. 1 to 9, a cooling plate 10 includes an upper plate 11 and a lower plate 12.

The cooling plate 10 is formed by coupling the upper plate 11 and the lower plate 12.

The upper plate 11 and the lower plate 12 form the appearance of the cooling plate 10. That is, the appearance of the cooling plate 10 is formed by coupling the exterior of the upper plate 11 and the exterior of the lower plate 12. The upper plate 11 and the lower plate 12 serve as a case of the cooling plate 10.

The cooling plate 10 has an inner space 10s.

Specifically, when the upper plate 11 and the lower plate 12 are coupled, the inner space 10s is formed between the upper plate 11 and the lower plate 12. Cooling fins 121 to be described later are arranged in the inner space 10s.

The upper plate 11 according to the disclosure may have a plate shape with a preset size and a preset thickness. The preset size refers to a size having a length in a horizontal direction and a length in a vertical direction, constituting a two-dimensional plane. The horizontal direction refers to an X-direction in FIG. 1, the vertical direction refers to a Y-direction in FIG. 1, and a thickness direction of the upper plate 11 refers to a Z-direction in FIG. 1.

The upper plate 11 includes an upper surface 11a, a lower surface 11b, and side surfaces 11c. The side surfaces 11c are surfaces connecting the upper surface 11a and the lower surface 11b, and surfaces forming the thickness between the upper surface 11a and the lower surface 11b.

The upper surface 11a, lower surface 11b, and side surfaces 11c of the upper plate 11 may include steps, curves, grooves, or holes as needed.

The upper plate 11 includes an upper plate groove 111.

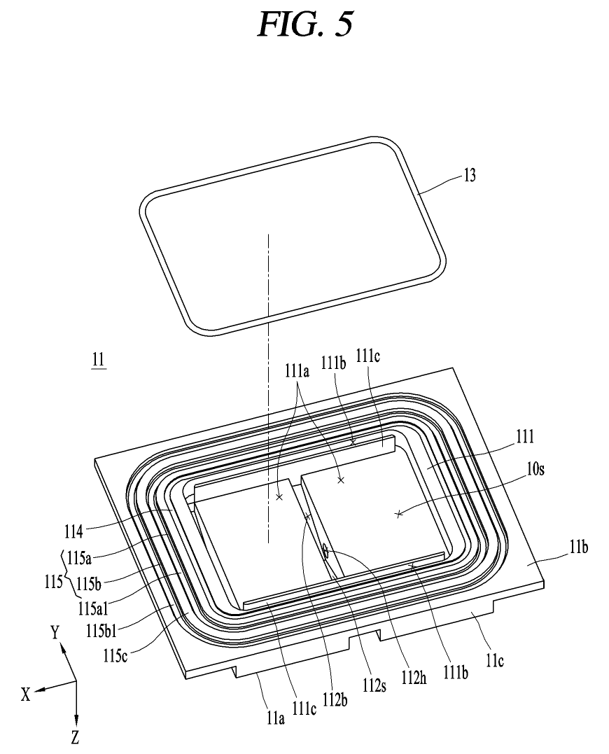

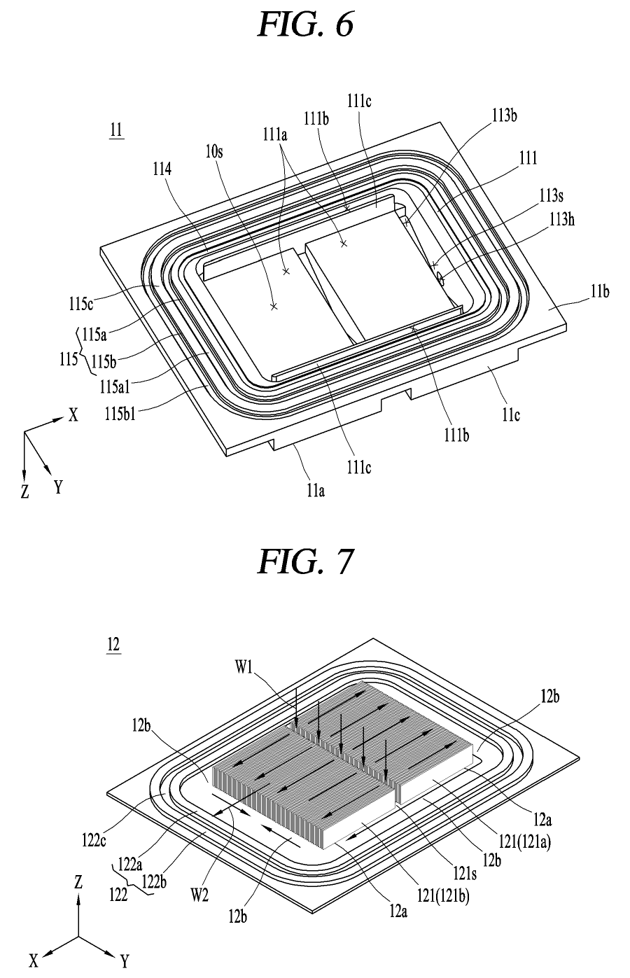

FIGS. 5 and 6 are views of the upper plate 11 of FIG. 1 turned over so that the lower surface 11b of the upper plate 11 is visible. The lower surface 11b of the upper plate 11 faces upward.

In FIG. 5, a left side of the upper plate 11 refers to a side where an outlet 113h is arranged, and a middle side refers to a side where an inlet 112h is arranged. In FIG. 6, a right side of the upper plate 11 refers to the side where the outlet 113h is arranged, and a middle side refers to the side where the inlet 112h is arranged.

The upper plate groove 111 is formed on the lower surface 11b of the upper plate 11, and is formed by being recessed from the lower surface 11b of the upper plate 11 toward the upper surface 11a by a preset depth.

More precisely, an opening of the upper plate groove 111 is formed at the lower surface 11b, and a bottom surface of the upper plate groove 111 is formed on a side toward the upper surface 11a (an opposite side to the opening). The bottom surface of the upper plate groove 111 may correspond to a ceiling surface because the opening of the upper plate groove 111 is located at the bottom.

The upper plate groove 111 faces the lower plate 12. Specifically, the lower plate 12 is coupled to the lower surface 11b of the upper plate 11 and covers the upper plate groove 111. That is, the lower plate 12 covers the opening of the upper plate groove 111.

When the upper plate 11 and the lower plate 12 are coupled, the upper plate groove 111 becomes the inner space 10s of the cooling plate 10.

The upper plate groove 111 has a preset size and a preset depth. The preset size refers to a size having a length in a horizontal direction and a length in a vertical direction, constituting a two-dimensional plane. The horizontal direction refers to the X-direction in FIG. 1, the vertical direction refers to the Y-direction in FIG. 1, and the depth of the upper plate groove 111 refers to the Z-direction in FIG. 1.

The upper plate groove 111 includes a fin area 111a, and an edge area 111b surrounding the fin area 111a. In other words, the upper plate groove 111 may be divided into the fin area 111a and the edge area 111b. The fin area 111a is located inside the edge area 111b.

When the upper plate 11 and the lower plate 12 are coupled, a plurality of cooling fins 121 are arranged in the fin area 111a, and the edge area 111b becomes an empty space. The edge area 111b becomes a flow path through which coolant flows.

Coolant which flows into the upper plate groove 111 through the inlet 112h passes between the cooling fins 121 to reach the edge area 111b, and flows along the edge area 111b to reach the outlet 113h. The coolant moves to the outside of the cooling plate 10 through the outlet 113h.

The cooling plate 10 according to the disclosure includes the inlet 112h and the outlet 113h.

The inlet 112h is a hole through which coolant flows into the cooling plate 10, and the outlet 113h is a hole through which the coolant flows out of the cooling plate 10.

According to a first embodiment of the disclosure, the upper surface 11a of the upper plate 11 may include a plurality of protrusions 112 and 113 (see FIG. 1). The protrusions 112 and 113 are each formed by protruding upward from the upper surface 11a of the upper plate 11 and have a space inside. The appearance of the protrusions 112 and 113 may be formed as a polyhedron.

The plurality of protrusions 112 and 113 include an inlet protrusion 112 and an outlet protrusion 113.

The inlet protrusion 112 is formed in a center area of the upper plate 11 in the horizontal direction (X-direction in FIG. 1) of the upper plate 11. The outlet protrusion 113 may be formed on one side (for example, a left side) of the upper plate 11 in the horizontal direction (X-direction in FIG. 1) of the upper plate 11.

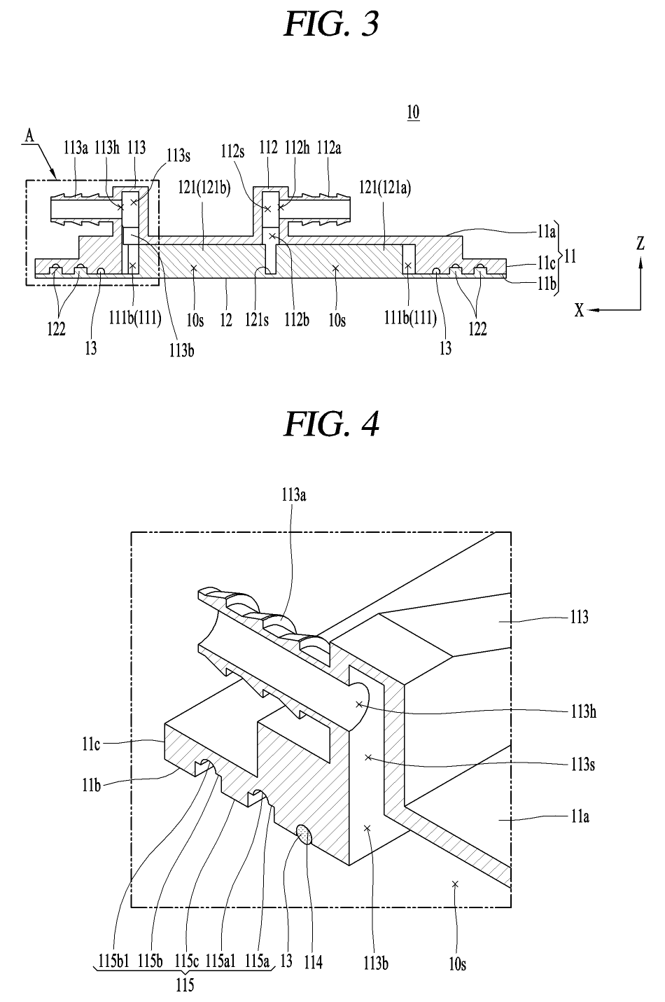

The inlet protrusion 112 is formed above an inlet passage 112b (see FIG. 3) to be described later, and an inner space 112s of the inlet protrusion 112 communicates with the inlet passage 112b. The inlet 112h is formed on one surface of the inlet protrusion 112, and penetrates the one surface of the inlet protrusion 112 to communicate with the inner space 112s of the inlet protrusion 112.

The outlet protrusion 113 is formed above an outlet passage 113b (see FIG. 3) to be described later, and an inner space 113s of the outlet protrusion 113 communicates with the outlet passage 113b. The outlet 113h is formed on one surface of the outlet protrusion 113, and penetrates the one surface of the outlet protrusion 113 to communicate with the inner space 113s of the outlet protrusion 113.

The inner spaces 112s and 113s of the inlet protrusion 112 and the outlet protrusion 113 may each have a volume that gradually decreases in a direction in which the inlet protrusion 112 and the outlet protrusion 113 protrude. The inlet 112h may be formed at an upper end of one surface of the inlet protrusion 112, and the outlet 113h may be formed at an upper end of one surface of the outlet protrusion 113.

Coolant flows into the inner space 112s of the inlet protrusion 112 through the inlet 112h, and then moves to the upper plate groove 111 through the inlet passage 112b. The coolant moves between the cooling fins 121 arranged in the upper plate groove 111, then passes through the edge area 111b of the upper plate groove 111, and moves to the outside of the cooling plate 10 according to the disclosure sequentially via the outlet passage 113b, the inner space 113s of the outlet protrusion 113, and the outlet 113h.

According to a second embodiment of the disclosure, the inlet protrusion 112 and the outlet protrusion 113 are not arranged, and the inlet and the outlet may be formed in the upper plate.

In the second embodiment, the inlet and the outlet may be formed at the positions of the inlet protrusion 112 and outlet protrusion 113 described above.

The inlet and the outlet are formed from the upper surface 11a of the upper plate 11 toward the lower surface 11b.

The inlet communicates with the inlet passage 112b, and the outlet communicates with the outlet passage 113b. The inlet passage 112b and the outlet passage 113b communicate with the upper plate groove 111.

Meanwhile, the cooling plate 10 according to the disclosure includes the inlet passage 112b and the outlet passage 113b.

The inlet passage 112b and the outlet passage 113b are spaces which are formed in the upper plate 11 and through which coolant flows.

The inlet passage 112b communicates with the inner space 112s of the inlet protrusion 112 (First embodiment) or the inlet (Second embodiment), and the outlet passage 113b communicates with the inner space 113s of the outlet protrusion 113 (First embodiment) or the outlet (Second embodiment). Accordingly, the inlet passage 112b is formed on the side of the inlet protrusion 112 or the inlet, and the outlet passage 113b is formed on the side of the outlet protrusion 113 or the outlet.

The inlet passage 112b is formed in the center area of the upper plate groove 111 in the horizontal direction (X-direction in FIG. 1) of the upper plate 11. The outlet protrusion 113b may be formed on one side (for example, a left side) of the upper plate groove 111 in the horizontal direction (X-direction in FIG. 1) of the upper plate 11 (see FIGS. 1 to 3).

The inlet passage 112b and the outlet passage 113b may have a preset width in one direction and a preset length in a direction horizontally orthogonal to the one direction. The one direction refers to the X-direction in FIGS. 2 and 3, and the direction horizontally orthogonal to the one direction refers to the Y-direction in FIG. 2.

The inlet passage 112b and the outlet passage 113b may be formed by being recessed from the bottom surface of the upper plate groove 111 toward the upper surface 11a (in the Z-direction in FIGS. 2 and 3) by a preset depth.

Below the outlet passage 113b, the edge area 111b of the upper plate groove 111 is located.

The upper plate 11 includes a pair of inner partition walls 111c (see FIGS. 5 and 6).

The pair of inner partition walls 111c are formed in the upper plate groove 111.

The inner partition walls 111c each have a preset length (height) from the bottom surface of the upper plate groove 111 toward the opening of the upper plate groove 111. The height of the inner partition wall 111c may be equal to the depth of the upper plate groove 111.

The inner partition walls 111c are formed between the fin area 111a and the edge area 111b, thereby partitioning the fin area 111a and the edge area 111b. However, the inner partition walls 111c are not formed everywhere between the fin area 111a and the edge area 111b.

Specifically, the pair of inner partition walls 111c are formed only in the horizontal direction (X-direction in FIGS. 5 and 6) of the upper plate groove 111, and are not formed in the vertical direction (Y-direction in FIGS. 5 and 6) of the upper plate groove 111.

In detail, the pair of inner partition walls 111c are formed between the fin area 111a and the edge area 111b corresponding to the horizontal direction of the upper plate groove 111, and are not formed between the fin area 111a and the edge area 111b corresponding to the vertical direction of the upper plate groove 111.

The pair of inner partition walls 111c are spaced apart by a distance of the fin area 111a corresponding to the vertical direction of the upper plate groove 111.

The inner partition wall 111c has a preset length in the horizontal direction of the upper plate groove 111. In detail, the inner partition wall 111c is formed as long as the length of the fin area 111a corresponding to the horizontal direction of the upper plate groove 111, in the fin area 111a of the upper plate groove 111.

The inner partition walls 111c blocks coolant flowing into the upper plate groove 111 from flowing directly to the edge area 111b of the upper plate groove 111 without passing between the cooling fins 121 to be described later.

As the pair of inner partition walls 111c ensure that entire coolant flowing into the upper plate groove 111 passes between the cooling fins 121, cooling efficiency of the cooling plate 10 is maximized.

A portion where the upper plate 11 and the lower plate 12 are coupled is sealed. This suppresses coolant from leaking between the upper plate 11 and the lower plate 12.

Referring to FIGS. 3 to 9, to seal a gap between the upper plate 11 and the lower plate 12, the cooling plate 10 according to the disclosure includes an O-ring groove 114, a coupling groove 115, adhesive grooves 115a1 and 115b1, and a coupling protrusion 122.

The O-ring groove 114, the coupling groove 115, and the adhesive grooves 115a1 and 115b1 are formed on the upper plate 11, and the coupling protrusion 122 is formed on the lower plate 12.

In addition, the cooling plate 10 according to the disclosure includes an O-ring member 13 and an adhesive member 14 to ensure sealing between the upper plate 11 and the lower plate 12.

The O-ring member 13 refers to a commonly used O-ring.

As is well known, the O-ring member 13 (O-ring) refers to a rubber ring commonly used in machinery, and serves as a packing to block a gap between members.

The O-ring member 13 (O-ring) is well known, and thus a detailed description thereof is omitted.

The adhesive member 14 refers to a commonly used adhesive.

As is known, the adhesive member 14 (adhesive) may be a polymer material having the property of bonding members.

The adhesive member 14 may be, for example, a silicone material. However, the adhesive member 14 is not limited thereto and may be made of various materials.

The adhesive member 14 (adhesive) is well known, and thus a detailed description thereof is omitted.

Hereinafter, the O-ring groove 114, the coupling groove 115, and the adhesive grooves 115a1 and 115b1 formed on the upper plate 11 will be described, and the coupling protrusion 122 formed on the lower plate 12 will be described in the description of the lower plate 12.

The O-ring groove 114 is formed on the lower surface 11b of the upper plate 11.

The O-ring member 13 is inserted and arranged into the O-ring groove 114.

The O-ring groove 114 is formed in a band shape with a preset width and surrounds the upper plate groove 111.

The O-ring groove 114 is spaced apart from the upper plate groove 111 by a preset distance.

The O-ring groove 114 is formed by being recessed from the lower surface 11b of the upper plate 11 toward the upper surface 11a by a preset depth.

The depth of the O-ring groove 114 is formed to be smaller than a thickness of the O-ring member 13.

In detail, when the O-ring member 13 is inserted into the O-ring groove 114, a portion of the O-ring member 13 protrudes from the O-ring groove 114. Accordingly, when the upper plate 11 and the lower plate 12 are coupled, the O-ring member 13 is compressed, thereby improving sealing performance between the upper plate 11 and the lower plate 12. The thickness of the O-ring member 13 refers to a thickness of a cross-section of the O-ring member 13.

The coupling groove 115 is formed on the lower surface 11b of the upper plate 11.

At least two coupling grooves 115 may be formed on the lower surface 11b of the upper plate 11. The drawing shows an embodiment in which two coupling grooves 115 are formed.

Hereinafter, a specific description of the coupling groove 115 is given of an embodiment in which two coupling grooves 115 are formed as shown in the drawing.

The two coupling grooves 115 refer to a first coupling groove 115a and a second coupling groove 115b.

A first coupling protrusion 122a of the lower plate 12 is inserted and arranged into the first coupling groove 115a, and a second coupling protrusion 122b of the lower plate 12 is inserted and arranged into the second coupling groove 115b.

The first coupling groove 115a is formed in a band shape with a preset width and surrounds the O-ring groove 114. The first coupling groove 115a is spaced apart from the O-ring groove 114 by a preset distance.

The second coupling groove 115b is formed in a band shape with a preset width and surrounds the first coupling groove 115a. The second coupling groove 115b is spaced apart from the first coupling groove 115a by a preset distance. In FIG. 4, a reference numeral 115c denotes a surface located between the first coupling groove 115a and the second coupling groove 115b.

Each of the first coupling groove 115a and the second coupling groove 115b is formed by being recessed from the lower surface 11b of the upper plate 11 toward the upper surface 11a by a preset depth.

More precisely, an opening of the first coupling groove 115a is formed in the lower surface 11b, and a bottom surface of the first coupling groove 115a is formed on a side toward the upper surface 11a (an opposite side to the opening). The bottom surface of the first coupling groove 115a may correspond to a ceiling surface because the opening of the first coupling groove 115a is located at the bottom. This also applies to the second coupling groove 115b.

A cross-sectional shape of the first coupling groove 115a and a cross-sectional shape of the first coupling protrusion 122a arranged on the lower plate 12 may correspond to each other. For example, the cross-sectional shape of the first coupling groove 115a and the cross-sectional shape of the first coupling protrusion 122a may be formed in a rectangular shape. Accordingly, when the first coupling protrusion 122a is inserted into the first coupling groove 115a, a gap between the first coupling protrusion 122a and the first coupling groove 115a can be minimized. This also applies to the second coupling groove 115b.

The cross-sectional shape of the first coupling groove 115a (or the first coupling protrusion 122a) described above represents a shape of a cut cross-section when the first coupling groove 115a (or the first coupling protrusion 122a) is cut in a direction orthogonal to a longitudinal direction of the first coupling groove 115a (or the first coupling protrusion 122a).

According to embodiments of the disclosure, the first coupling groove 115a is formed in a band shape with a preset length and surrounds the O-ring groove 114. The second coupling groove 115b is formed in a band shape with a preset length and surrounds the first coupling groove 115a.

In these embodiments, each of the first coupling groove 115a and the second coupling groove 115b may be formed in a band shape which is seamlessly connected as shown in the drawing, or may be formed with at least one portion disconnected in a middle thereof to have at least two sections. The sections may each have a preset length, and the coupling protrusion 122 may be inserted into each section. The presence of the disconnected portion in the middle means that the coupling groove 115 is not formed between the sections.

Meanwhile, the adhesive grooves 115a1 and 115b1 are formed in the coupling groove 115. Specifically, a first adhesive groove 115a1 is formed in the first coupling groove 115a, and a second adhesive groove 115b1 is formed in the second coupling groove 115b.

The first adhesive groove 115a1 and the second adhesive groove 115b1 accommodate the adhesive member 14. When the adhesive member 14 is applied to a certain area of the lower surface 11b of the upper plate 11, the adhesive member 14 flows into the first adhesive groove 115a1 and the second adhesive groove 115b1 and fills each of the first and second adhesive grooves 115a1 and 115b1.

The first adhesive groove 115a1 communicates with the first coupling groove 115a, and the second adhesive groove 115b1 communicates with the second coupling groove 115b.

The first adhesive groove 115a1 is formed on the bottom surface of the first coupling groove 115a, and is formed by being recessed from the bottom surface of the first coupling groove 115a toward the upper surface 11a by a preset depth.

The second adhesive groove 115b1 is formed on the bottom surface of the second coupling groove 115b, and is formed by being recessed from the bottom surface of the second coupling groove 115b toward the upper surface 11a by a preset depth.

In detail, an opening of the first adhesive groove 115a1 is formed in the bottom surface of the first coupling groove 115a, and a bottom surface of the first adhesive groove 115a1 is formed on a side toward the upper surface 11a (a side opposite to the opening). The bottom surface of the first adhesive groove 115a1 may correspond to a ceiling surface because the opening of the first adhesive groove 115a1 is located at the bottom. This also applies to the second coupling groove 115b.

In a state where the upper plate 11 is arranged so that the upper surface 11a faces upward and the lower surface 11b faces downward (see FIGS. 3 and 4), the first adhesive groove 115a1 is arranged on an upper side of the first coupling groove 115a, and the second adhesive groove 115b1 is arranged on an upper side of the second coupling groove 115b.

In an embodiment in which three coupling grooves 115 are formed according to an embodiment of the disclosure, the arrangement relationship of the first coupling groove 115a and the second coupling groove 115b described above is applied in the same manner, and a third coupling groove is formed in a band shape with a preset width and is arranged to surround the second coupling groove 115b described above. The third coupling groove is spaced apart from the second coupling groove 115b by a preset distance. A third adhesive groove may be formed in the third coupling groove.

Meanwhile, according to an embodiment of the disclosure, only one coupling groove 115 may be formed on the lower surface 11b of the upper plate 11. In this embodiment, the one coupling groove 115 may be any one (the first coupling groove 115a and the second coupling groove 115b) of the plurality of coupling grooves 115. One adhesive groove 115a1 or 115b1 may be formed in the one coupling groove 115.

Referring to FIGS. 1 to 3 and FIGS. 7 to 9, the lower plate 12 according to the disclosure may be formed in a plate shape having a preset size and a preset thickness. The preset size refers to a size having a length in a horizontal direction and a length in a vertical direction, constituting a two-dimensional plane. The horizontal direction refers to the X-direction in FIG. 2, the vertical direction refers to the Y-direction in FIG. 2, and a thickness direction of the cooling plate 10 refers to the Z-direction in FIG. 2.

The lower plate 12 includes an upper surface, a lower surface, and side surfaces. The side surfaces are surfaces connecting the upper surface and the lower surface, and surfaces which form a thickness between the upper surface and the lower surface.

The upper surface, lower surface, and side surfaces of the lower plate 12 may include steps, curves, and grooves as needed.

The upper surface of the lower plate 12 faces the lower surface 11b of the upper plate 11. The upper surface of the lower plate 12 covers the opening of the upper plate groove 111.

The cooling fins 121 are arranged or formed on the upper surface of the lower plate 12, and the lower surface of the lower plate 12 comes into contact with an upper surface of a chip, such as a CPU or GPU.

Referring to FIGS. 2 and 7, the lower plate 12 includes a fin area 12a corresponding to the fin area 111a of the upper plate groove 111, and also includes an edge area 12b corresponding to the edge area 111b of the upper plate groove 111. The fin area 12a and the edge area 12b are formed on the upper surface of the lower plate 12.

The fin area 12a of the lower plate 12 is located below the fin area 111a of the upper plate groove 111, and the edge area 12b of the lower plate 12 is located below the edge area 111b of the upper plate groove 111. Accordingly, the fin area 12a of the lower plate 12 is located within the edge area 12b.

The plurality of cooling fins 121 are arranged or formed in the fin area 12a of the lower plate 12.

The edge area 12b of the lower plate 12 is an empty space and becomes a flow path through which coolant flows.

The inner space 10s of the cooling plate 10 according to the disclosure may be divided into a fin area and an edge area. The fin area of the cooling plate 10 is formed by coupling the fin area 111a of the upper plate groove 111 and the fin area 12a of the lower plate 12, and the edge area of the cooling plate 10 is formed by coupling the edge area 111b of the upper plate groove 111 and the edge area 12b of the lower plate 12.

The cooling plate 10 according to the disclosure includes the plurality of cooling fins 121.

The cooling fins 121 may be connected to the lower plate 12 or may be formed on the lower plate 12.

The cooling fins 121 are formed by extending upward from one surface (e.g., the upper surface) of the lower plate 12 by a preset length.

The cooling fins 121 may be formed, for example, by skiving.

Referring to FIGS. 2, 3 and 7, the cooling fin 121 is formed in a plate shape with a preset size and a preset thickness. The preset size refers to a size having a length in a horizontal direction and a length in a vertical direction, constituting a two-dimensional plane. The horizontal direction refers to the X-direction in FIG. 2, the vertical direction refers to the Z-direction in FIG. 2, and a thickness direction of the cooling fin 121 refers to the Y-direction in FIG. 2.

The horizontal length of the cooling fin 121 may be formed to be longer than the vertical length.

The vertical length of the cooling fin 121 (the height of the cooling fin 121) may be equal to the depth of the upper plate groove 111. Accordingly, coolant flowing into the upper plate groove 111 cannot flow over the cooling fins 121, but moves between the cooling fins 121 and through the edge area 111b.

The cooling fins 121 may have the same thickness or different thicknesses.

Additionally, a gap between the cooling fins 121 adjacent to each other may be the same or different.

Additionally, for example, a distance between the cooling fins 121 in an area A may be different from a distance between the cooling fins 121 in an area B. At this time, the distance between the cooling fins 121 in the area A may be uniform, and the distance between the cooling fins 121 in the area B may also be uniform.

In this specification, a 'horizontal longitudinal direction of the cooling fin 121' may be simply referred to as a 'longitudinal direction of the cooling fin 121' and indicates the X-direction in the drawings of this specification.

In the fin area 12a of the lower plate 12, the plurality of cooling fins 121 may be arranged to form a plurality of groups 121a and 121b.

That is, the cooling plate 10 according to the disclosure may include a plurality of groups, each consisting of a plurality of cooling fins 121.

The plurality of groups 121a and 121b may include a first group 121a and a second group 121b. The first group 121a and the second group 121b are arranged between the pair of inner partition walls 111c.

Each of the first group 121a and the second group 121b includes a plurality of cooling fins 121.

In the first group 121a and the second group 121b, each of the plurality of cooling fins 121 is arranged in one direction. The one direction indicates the horizontal direction (longitudinal direction) of the cooling fin 121.

In detail, the cooling fins 121 is arranged so that a horizontal direction of the cooling fins 121 is parallel to the X-direction in FIGS. 2 and 3 and FIGS. 5 to 7.

The cooling fins 121 each have a preset length in the horizontal direction of the upper plate groove 111.

The longitudinal direction of the cooling fins 121 may be parallel to the longitudinal direction of the inner partition walls 111c.

In the first group 121a and the second group 121b, each of the plurality of cooling fins 121 is arranged in a row in another direction. The other direction refers to a direction horizontally orthogonal to the one direction and refers to a thickness direction of the cooling fins 121 (e.g., the Y-direction in FIGS. 2 and 3 and FIGS. 5 to 7).

The first group 121a and the second group 121b are arranged side by side in one direction (e.g., the X-direction in FIGS. 2 and 3 and FIGS. 5 to 7) and are arranged spaced apart from each other by a certain distance.

A space 121s where the first group 121a and the second group 121b are spaced from each other is located within the fin area 12a of the lower plate 12.

The inlet passage 112b of the upper plate 11 is arranged above the space 121s where the first group 121a and the second group 121b are spaced apart from each other. Accordingly, coolant flowing into the inlet passage 112b through the inlet 112h flows to the space 121s where the first group 121a and the second group 121b are spaced apart from each other (W1 in FIG. 7, an arrow in FIG. 7 indicates a movement path of the coolant).

The coolant flows into the first group 121a and the second group 121b, and flows between the plurality of cooling fins 121 in the first group 121a and the second group 121b.

The coolant in the space 121s where the first group 121a and the second group 121b are spaced from each other is suppressed from moving directly to the edge area 111b by the pair of inner partition walls 111c, and flows between the plurality of cooling fins 121 in the first group 121a and the second group 121b so as to move to the edge area 111b (see FIGS. 5 to 7).

Accordingly, the entire coolant introduced into the space 121s where the first group 121a and the second group 121b are spaced apart from each other passes between the cooling fins 121, thereby improving cooling efficiency of the cooling plate 10.

Then, the coolant passes through the edge area 111b of the upper plate groove 111, and moves to the outside of the cooling plate 10 according to the disclosure sequentially via the outlet passage 113b, the inner space 113s of the outlet protrusion 113, and the outlet 113h.

The inlet 112h may be arranged in the middle of the space 121s between the first group 121a and the second group 121b. The middle of the space 121s indicates a middle portion in the Y-direction of the fin area 111a shown in FIG. 2.

Below the space 121s where the first group 121a and the second group 121b are spaced, a circuit component (e.g., a chip, such as a CPU or GPU) which is a high-heat source may be arranged, or a portion of the circuit component from which high heat is generated may be arranged.

Accordingly, the coolant flowing out of the inlet 112h directly hits the lower plate 12 on the circuit component of the high-heat source or the portion where high heat is generated, thereby further increasing the cooling efficiency of the cooling plate 10.

The horizontal length of the cooling fin 121 in the first group 121a and the horizontal length of the cooling fin 121 in the second group 121b may be the same or different. Accordingly, the positions of the space 121s between the first group 121a and the second group 121b, the inlet protrusion 112, and the inlet 112h can change.

Meanwhile, in an embodiment (not shown) in which there are at least three groups each consisting of the cooling fins 121, there may be at least two spaces 121s between the adjacent groups, and the inlet protrusion 112 and/or the inlet 112h may be arranged at each of the spaces 121s.

To seal a gap between the upper plate 11 and the lower plate 12, the lower plate 12 includes the coupling protrusion 122 (see FIGS. 2 and 3 and FIGS. 7 to 9).

The coupling protrusion 122 is formed on the upper surface of the lower plate 12.

When the upper plate 11 and the lower plate 12 are coupled, the coupling protrusion 122 is inserted and arranged into the coupling groove 115 of the upper plate 11.

The coupling protrusion 122 on the lower plate 12 is formed to be located below the coupling groove 115 of the upper plate 11.

At least two coupling protrusions 122 may be formed on the upper surface of the lower plate 12. The drawing shows an embodiment in which two coupling protrusions 122 are formed to correspond to the number of coupling grooves 115.

Hereinafter, a specific description of the coupling protrusion 122 is given of an embodiment in which two coupling protrusions 122 are formed as shown in the drawing.

The two coupling protrusions 122 indicate a first coupling protrusion 122a and a second coupling protrusion 122b.

The first coupling protrusion 122a is inserted and arranged into the first coupling groove 115a of the upper plate 11, and the second coupling protrusion 122b is inserted and arranged into the second coupling groove 115b of the upper plate 11.

The first coupling protrusion 122a is formed in a band shape with a preset width and surrounds the edge area 12b of the lower plate 12.

When the upper plate 11 and the lower plate 12 are coupled, the first coupling protrusion 122a is spaced apart from the O-ring member 13 arranged in the O-ring groove 114 of the upper plate 11 by a preset distance.

The second coupling protrusion 122b is formed in a band shape with a preset width and surrounds the first coupling protrusion 122a. The second coupling protrusion 122b is spaced apart from the first coupling protrusion 122a by a preset distance. In FIG. 7, a reference numeral 122c denotes a surface located between the first coupling protrusion 122a and the second coupling protrusion 122b.

Each of the first coupling protrusion 122a and the second coupling protrusion 122b is formed to protrude from the upper surface of the lower plate 12 toward the upper plate 11 by a preset length (height).

According to embodiments of the disclosure, the first coupling protrusion 122a is formed in a band shape having a preset length and surrounds the edge area 12b of the lower plate 12. The second coupling protrusion 122b is formed in a band shape with a preset length and surrounds the first coupling protrusion 122a.

In these embodiments, each of the first coupling protrusion 122a and the second coupling protrusion 122b may be formed in a band shape which is seamlessly connected as shown in the drawing, or may be formed with at least one portion disconnected in a middle thereof to have at least two sections. The sections may each have a preset length, and may be inserted into the coupling groove 115. The presence of the disconnected portion in the middle means that the coupling protrusion 122 is not formed between the sections.

Meanwhile, when the upper plate 11 and the lower plate 12 are coupled and the first coupling protrusion 122a of the lower plate 12 is inserted into the first coupling groove 115a of the upper plate 11, the first adhesive groove 115a1 is arranged on an upper surface of the first coupling protrusion 122a (see FIG. 8).

When the second coupling protrusion 122b of the lower plate 12 is inserted into the second coupling groove 115b of the upper plate 11, the second adhesive groove 115b1 is arranged on an upper surface of the second coupling protrusion 122b (see FIG. 8).

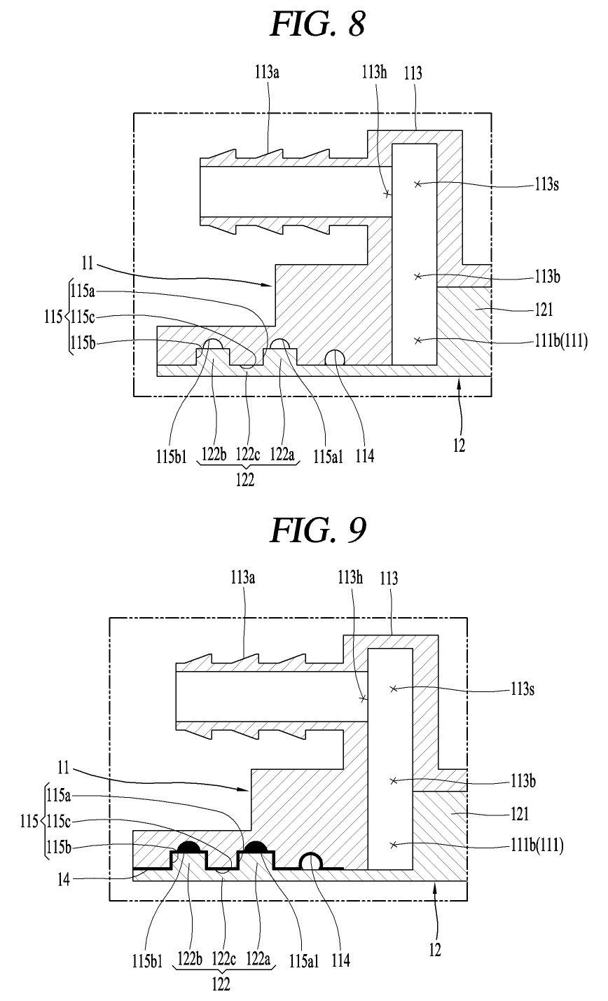

When the adhesive member 14 is applied to a certain area of the lower surface 11b of the upper plate 11 before the upper plate 11 and the lower plate 12 are coupled, the adhesive member 14 is introduced into the O-ring groove 114, the first adhesive groove 115a1, and the second adhesive groove 115b1 to fill the O-ring groove 114, the first adhesive groove 115a1, and the second adhesive groove 115b1 (see FIG. 9).

An area where the adhesive material 14 is applied to the lower surface 11b of the upper plate 11 refers to an area surrounding the upper plate groove 111 of the upper plate 11.

In detail, the adhesive material 14 may be applied to an area where the O-ring groove 114, the first coupling groove 115a, and the second coupling groove 115b, excluding the upper plate groove 111, are formed, and a surrounding area of the area, on the lower surface 11b of the upper plate 11 (see FIG. 9).

After the adhesive member 14 is applied to the lower surface 11b of the upper plate 11, the O-ring member 13 is inserted into the O-ring groove 114, and the upper plate 11 and the lower plate 12 are coupled.

The adhesive member 14 is arranged between the O-ring groove 114 and the O-ring member 13.

The inner surface of the O-ring groove 114 and the outer surface of the O-ring member 13 are coupled by the adhesive member 14. Accordingly, the O-ring member 13 is fixed without being easily separated from the O-ring groove 114.

The adhesive member 14 is arranged between the coupling groove 115 (the first coupling groove 115a and the second coupling groove 115b) and the coupling protrusion 122 (the first coupling protrusion 122a and the second coupling protrusion 122b).

The inner surface of the coupling groove 115 and the outer surface of the coupling protrusion 122 are coupled by the adhesive member 14. Accordingly, the coupling protrusion 122 is fixed without being easily separated from the coupling groove 115.

In this way, the adhesive member 14 serves to fix the O-ring member 13 and the coupling protrusion 122 to the upper plate 11.

The adhesive member 14 serves to suppress coolant in the inner space 10s (the upper plate groove 111 of the upper plate 11) of the cooling plate 10 from leaking into a gap between the upper plate 11 and the lower plate 12, and also serve to couple the upper plate 11 and the lower plate 12.

The coolant flowing into the inner space 10s of the cooling plate 10 is subjected to preset pressure for smooth movement. More precisely, preset pressure is applied to the coolant to ensure smooth movement of the coolant within the cooling plate 10.

The O-ring member 13, the adhesive member 14, and the coupling protrusion 122 suppress the coolant from leaking between the upper plate 11 and the lower plate 12 at the preset pressure applied to the coolant and pressure higher than the preset pressure.

The first adhesive groove 115a1 and the second adhesive groove 115b1 improve coupling strength between the upper plate 11 and the lower plate 12 and enhance leakage suppression capability of the cooling plate 10.

In detail, the first adhesive groove 115a1 and the second adhesive groove 115b1 accommodate a certain amount of adhesive member 14. Accordingly, the adhesive member 14 accommodated in the first adhesive groove 115a1 and the second adhesive groove 115b1 improves the coupling strength between the upper plate 11 and the lower plate 12 and the leakage suppression capability of the cooling plate 10 together with the adhesive member 14 applied to the surface of the lower surface 11b of the upper plate 11.

The first coupling protrusion 122a and the second coupling protrusion 122b improve the coupling strength between the upper plate 11 and the lower plate 12 and enhance the leakage suppression capability of the cooling plate 10.

In detail, the first coupling protrusion 122a and the second coupling protrusion 122b trap a certain amount of adhesive member 14 between the first coupling protrusion 122a and the second coupling protrusion 122b, thereby improving the coupling strength between the upper plate 11 and the lower plate 12 and the leakage suppression performance of the cooling plate 10.

In an embodiment in which three coupling protrusions 122 are formed according to an embodiment of the disclosure, the arrangement relationship of the first coupling protrusion 122a and the second coupling protrusion 122b described above is applied in the same manner, and a third coupling protrusion is formed in a band shape with a preset width and is arranged to surround the second coupling protrusion 122b described above. The third coupling protrusion is spaced apart from the second coupling protrusion 122b by a preset distance.

Meanwhile, in the embodiment in which only one coupling groove 115 is formed on the lower surface 11b of the upper plate 11 as described above, only one coupling protrusion 122 may be formed on the lower surface 11b of the upper plate 11.

For example, in this embodiment, when one coupling groove 115 is the first coupling groove 115a, the first coupling protrusion 122a may be formed, and when one coupling groove 115 is the second coupling groove 115b, the second coupling protrusion 122b may be formed.

According to another embodiment of the disclosure, the O-ring groove 114 may be formed between the first coupling groove 115a and the second coupling groove 115b, or may be formed on the edge side of the lower surface 11b of the upper plate 11 to surround the second coupling groove 115b.

As described above, to seal the gap between the upper plate 11 and the lower plate 12, the upper plate 11 according to the disclosure includes the O-ring groove 114, the coupling groove 115, and the adhesive grooves 115a1 and 115b1, and the lower plate 12 includes the coupling protrusion 122. The cooling plate 10 according to the disclosure includes the O-ring member 13 and the adhesive member 14.

The O-ring groove 114, the coupling groove 115, the adhesive grooves 115a1 and 115b1, the coupling protrusion 122, the O-ring member 13, and the adhesive member 14 may be referred to as 'sealing components'.

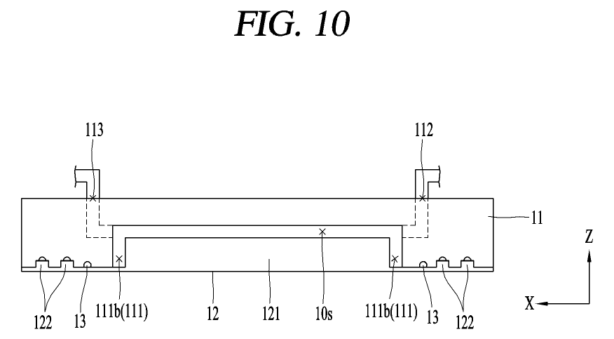

The sealing components may also be applied to a cooling plate (another cooling plate) according to another embodiment. FIG. 10 is a schematic view of an embodiment in which the sealing components are applied to another cooling plate.

In detail, even when the other cooling plate includes an upper plate 11 and a lower plate 12, and the shape of the upper plate 11 and the shape of the lower plate 12 of the other cooling plate are different from the shape of the upper plate 11 and the shape of the lower plate 12 according to the disclosure described above, the sealing components may be formed or arranged at a portion where one surface (e.g., a lower surface) of the upper plate 11 of the other cooling plate and one surface (e.g., an upper surface) of the lower plate 12 are in contact with each other.

In FIG. 1, a reference numeral 112a denotes an inlet connection portion, and a reference numeral 113a denotes an outlet connection portion.

One end of the inlet connection portion 112a is connected to the inlet 112h, and the other end is connected to a first pipe (not shown). That is, the inlet connection portion 112a is a member which is arranged between the inlet 112h and the first pipe to connect the inlet 112h and the first pipe.

One end of the outlet connection portion 113a is connected to the outlet 113h, and the other end is connected to a second pipe (not shown). That is, the outlet connection portion 113a is a member which is arranged between the outlet 113h and the second pipe to connect the outlet 113h and the second pipe.

The cooling plate 10 according to the disclosure has the cooling fins 121 arranged such that coolant does not pressurize one surface of the cooling fins 121 in a direction orthogonal to the one surface of the cooling fin 121, thereby minimizing pressure that the coolant applies to the cooling fin 121. This minimizes overall power consumption of a cooling system.

The cooling plate 10 according to the disclosure distributes coolant to move between the cooling fins 121, thereby reducing pressure loss of the coolant and improving cooling efficiency.

The cooling plate 10 according to the disclosure allows coolant to move along the longitudinal direction of the cooling fins 121, thereby reducing flow resistance of the coolant.

In this way, the cooling plate 10 according to the disclosure enhances heat transfer performance and hydraulic performance, thereby obtaining an effect of maximizing the cooling efficiency.

In addition, the cooling plate 10 according to the disclosure includes the sealing components to maximize the leakage suppression performance of the cooling plate 10. There is also an effect that the sealing components can apply to other cooling plates as well.

What is claimed is:

1. A cooling plate configured to remove heat from a circuit component, the cooling plate comprising:
an upper plate comprising an inlet through which coolant flows in and an outlet through which the coolant flows out; and
a lower plate coupled to the upper plate and comprising a plurality of cooling fins arranged thereon,
wherein the upper plate further comprises an O-ring groove in which an O-ring member is arranged, and
the O-ring member is compressed when the upper plate and the lower plate are coupled to each other.

2. The cooling plate of claim 1, wherein the upper plate further comprises an upper plate groove accommodating the plurality of cooling fins, and
the O-ring groove is formed in a band shape with a preset width and surrounds the upper plate groove.

3. The cooling plate of claim 2, wherein the upper plate further comprises a first coupling groove, and
the first coupling groove is formed in a band shape with a preset width and surrounds the O-ring groove.

4. The cooling plate of claim 3, wherein a first adhesive groove is formed in the first coupling groove,
the first adhesive groove communicates with the first coupling groove and accommodates an adhesive member, and
the first adhesive groove is formed on a bottom surface of the first coupling groove and is formed by being recessed from the bottom surface of the first coupling groove toward an upper surface of the upper plate by a preset depth.

5. The cooling plate of claim 3, wherein the lower plate further comprises a first coupling protrusion inserted into the first coupling groove, and
the first coupling protrusion is formed in a band shape with a preset width and is formed by protruding from an upper surface of the lower plate toward the upper plate by a preset length.

6. The cooling plate of claim 5, further comprising an adhesive member,
wherein the adhesive member is applied to the first coupling groove, so as to be arranged between the first coupling groove and the first coupling protrusion.

7. The cooling plate of claim 3, wherein the upper plate further comprises a second coupling groove, and
the second coupling groove is formed in a band shape with a preset width and surrounds the first coupling groove.

8. The cooling plate of claim 7, wherein a second adhesive groove is formed in the second coupling groove,
the second adhesive groove communicates with the second coupling groove and accommodates an adhesive member, and
the second adhesive groove is formed on a bottom surface of the second coupling groove and is formed by being recessed from the bottom surface of the second coupling groove toward an upper surface of the upper plate by a preset depth.

9. The cooling plate of claim 7, wherein the lower plate further comprises a second coupling protrusion inserted into the second coupling groove, and
the second coupling protrusion is formed in a band shape with a preset width and is formed by protruding from an upper surface of the lower plate toward the upper plate by a preset length.

10. The cooling plate of claim 9, further comprising an adhesive member,
wherein the adhesive member is applied to the second coupling groove, so as to be arranged between the second coupling groove and the second coupling protrusion.

11. The cooling plate of claim 1, wherein the upper plate further comprises an inlet passage communicating with the inlet, an outlet passage communicating with the outlet, and an upper plate groove accommodating the plurality of cooling fins, and
a height of the cooling fin is equal to a depth of the upper plate groove.

12. The cooling plate of claim 11, wherein the upper plate groove and the lower plate each comprise a fin area where the plurality of cooling fins are arranged, and an edge area surrounding the fin area, and
coolant flowing into the upper plate groove passes between the cooling fins, reaches the edge area, and moves along the edge area.

13. The cooling plate of claim 12, wherein a pair of inner partition walls are formed in the upper plate groove, and
the pair of inner partition walls are formed between the fin area and the edge area corresponding to a horizontal direction of the upper plate groove, to partition the fin area and the edge area.

14. The cooling plate of claim 13, wherein a first group and a second group each consisting of the plurality of cooling fins are arranged between the pair of inner partition walls, and
a longitudinal direction of the cooling fins is arranged parallel to a longitudinal direction of the inner partition walls.

15. The cooling plate of claim 14, wherein the first group and the second group are arranged spaced apart from each other by a certain distance in the fin area of the lower plate, and
the inlet passage of the upper plate is located above a space where the first group and the second group are spaced apart from each other.
